(19) United States
(12) Patent Application Publication
(10) Pub. No.: US 2005/0230711 A1
(43) Pub. Date: Oct. 20, 2005

(54) [CIRCUIT CONNECTING STRUCTURE AND FABRICATING METHOD THEREOF]

(76) Inventors: Chin-Chung Chang, Taoyuan County (TW); Chia-Pin Lin, Taipei County (TW); Kwang-Shiang Juang, Taoyuan County (TW); Shao- Chien Lee, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,697

(22) Filed: Jul. 29, 2004

(30) Foreign Application Priority Data
Apr. 16, 2004 (TW) 93110638

(51) Int. Cl. H01L 27/10

(52) U.S. Cl. 257/210

(57) ABSTRACT

A connecting circuit structure is provided for a circuit carrier. The circuit connecting structure includes at least two insulating layers, two conductive layers, and one conductive pad, wherein a via hole is formed from each of the insulating layers through corresponding insulating layer. One insulating layer is formed over the other. The conductive pad is disposed between the two insulating layers, and two surfaces of the conductive pad are connected to the two via holes respectively. Two conductive layers are respectively formed in the via hole on a same side of the circuit connecting structure in order to connect to the conductive pad respectively. Since a depth/width ratio of the via hole is reduced according to the circuit connecting structure in the present invention, voids and bubbles are effectively avoided and the reliability of fabricating method thereof is increased.

### CROSS REFERENCE TO RELATED APPLICATIONS

This application claims the priority benefit of Taiwan application serial no. 93110638, filed Apr. 16, 2004.

### BACKGROUND OF INVENTION

1. Field of Invention

The present invention relates to a connecting structure, and more particularly, to a circuit connecting structure, where a depth/width ratio of a via hole is reduced under a fixed via hole width.

2. Description of the Related Art

As fabrication technology of electronics industry develops and proceeds rapidly, a printed circuit board (PCB) displaces conventional wiring welding assembly system.

Since a PCB is capable of disposing with miniature electronics parts, it is widely adopted by the industry. As an integrated circuit (IC) and a computer system are succeedingly invented, circuit design becomes increasingly intricate and complicated. Therefore, single layered PCB is not capable of serving for routing layout, whereas double-layered PCB and multi-layered PCB are disclosed as a consequence. In IC packaging field, a PCB not only serves as the motherboard of a computer system, but also serves as a substrate for IC packaging. In order to increase trace density within limited substrate dimension, increasing trace density is realized by coupling at least two patterned circuit layers with at least one circuit connecting structure.

Referring to FIG. 1A, a schematic cross-sectional diagram of a circuit connecting structure is illustrated. In FIG. 1A, the circuit connecting structure 101 is a double-layered board, for example, hence a number of conductive layers is two. The conventional circuit connecting structure is applied to a circuit carrier (not illustrated), where the circuit carrier includes at least two patterned circuit layers (not illustrated). The circuit connecting structure 101 includes an insulating layer 110, two conductive layers 120 and 122, a via hole 130 and a conductive film 124, wherein the insulating layer 110 is generally composed of epoxy resin, and the conductive layers 120 and 122 are generally composed of copper. The conductive layers 120 and 122 are respectively disposed over two surfaces 112 and 114 of the insulating layer 110, and the via hole 130 of the circuit connecting structure 101 is formed by etching or direct laser drilling for penetrating through the conductive layer 120 and the insulating layer 110.

Referring to FIG. 1B, a schematic cross-sectional diagram of the circuit connecting structure of FIG. 1A is illustrated, where the conductive film is non-uniformly distributed over sidewalls of the via hole. In FIG. 1B, a conductive film 124, disposed over the circuit connecting structure 101 such that the via hole manages to electrically coupling the conductive layers 120 and 122, is formed by electroplating or plug electroplating. When the conductive film 124 forming the via hole 130, electronic charges aggregate around a tip area where the conductive layer 120 and the via hole 130 are joined, thus the conductive film 124 is thicker around the area thereof. In contrast, the conductive film 124 is thinner around the bottom of the via hole 130. Since the via hole 130 is generally formed with laser drilling process, the width thereof is usually consistent, yet the depth is usually too deep (about over 100 μm), thus a width/depth ratio is too high to form a uniform conductive film 124 in the via hole 130.

Referring to FIG. 1C, a schematic cross-sectional diagram of the circuit connecting structure is illustrated, where a void is formed with the conductive film. In FIG. 1C, when the thickness of the conductive film 124 is increased, the conductive film 124 around the top of the via hole 130 may be connected and closed. A void 140 is thus formed around the bottom of the via hole 130 where air is accommodated and a bubble is formed. Therefore reliability of fabricating conductive film 124 of the circuit connecting structure is reduced.

### SUMMARY OF INVENTION

According to one aspect of the present invention, a circuit connecting structure is provided, where a via hole is fabricated shallower as width thereof is fixed, so that a depth/width ratio of the via hole is relatively smaller, for avoiding a void or a bubble when a film is electroplated.

According to another aspect of the present invention, a fabricating method of a circuit connecting structure is provided, where a via hole is fabricated shallower as width thereof is fixed, so that a depth/width ratio of the via hole is relatively smaller, for avoiding a void or a bubble when a film is electroplated.

According to the present invention, a circuit connecting structure applied to a circuit carrier is provided, wherein the circuit carrier includes at least a first patterned circuit layer and a second patterned circuit layer. The connecting circuit structure includes a first insulating layer, a second insulating layer, a conductive pad, a first conductive layer and a second conductive layer, wherein the first insulating layer is penetrated with a first via hole. The second insulating layer is penetrated with a second via hole, and the second insulating layer is formed over the first insulating layer. The conductive pad is disposed between the first insulating layer and the second insulating layer, where the two surfaces of the conductive pad are respectively connected to the first via hole and the second via hole. The first conductive layer is disposed over the surface of the first insulating layer that is away from the second insulating layer, and is disposed in the first via hole for connecting to the conducting pad, for forming a first patterned circuit layer. The second conductive layer is disposed over the surface of the second insulating layer away from the first insulating layer, and is disposed in the second via hole for connecting to the conductive pad, for forming a second patterned circuit layer.

According to one aspect of the circuit connecting structure in the present invention, wherein the conductive pad, the first conductive layer, and the second conductive layer are composed of copper.

According to one aspect of the circuit connecting structure of the present invention, wherein the first insulating layer and the second insulating layer are comprised of epoxy resin.

According to another aspect of the present invention, a fabricating method of the circuit connecting structure applied to a circuit carrier is provided, wherein the circuit carrier includes a first patterned circuit layer and a second patterned circuit layer. The fabricating method of the circuit connecting structure includes the following steps.

First, forming a first conductive pad over a surface of a first insulating layer, and forming a first conductive layer over the other surface of the first insulating layer. Second, forming a second insulating layer over the surface of the first insulating layer and covering the conductive pad, and forming a second conductive layer over the off surface of the second insulating layer. Then, forming a first via hole from the first conductive layer through the first insulating layer for exposing the conductive pad, and forming a second via hole from the second conductive layer through the second insulating layer for exposing the conductive pad. Lastly, forming a third conductive layer in the first via hole for coupling the conductive pad to the first conductive layer, and defining the third conductive layer and the first conductive layer to form a first patterned circuit layer; and forming a fourth conductive layer in the second via hole for coupling the conductive layer to the second conductive layer, and defining the fourth conductive layer and the second conductive layer to form a second patterned circuit layer.

According to the above description, the connecting circuit structure is formed between two insulating layers with a conductive pad, and the two conductive layers are respectively disposed over an insulating layer and a via hole on a same side of the circuit connecting structure, such that two conductive layers are electronically coupled to each other via the conductive pad. Therefore, with a fixed width of the via holes, a depth of each via holes can be reduced as well as the width/depth ratio, such that the conductive layer in the via hole is more uniformly formed, and a void or a bubble thereof is effectively avoided according to the circuit connecting structure in the present invention.

### BRIEF DESCRIPTION OF DRAWINGS

FIG. 1A is a schematic diagram illustrating cross-sectional view of a circuit connecting structure according to conventional art.

FIG. 1B is a schematic diagram illustrating cross-sectional view of a circuit connecting structure according to conventional art where conductive layer is non-uniformly formed on the sidewalls of the via hole.

FIG. 1C is a schematic diagram illustrating cross-sectional view of a circuit connecting structure according to conventional art where part of the conductive layer is connected and a void is formed thereby.

FIG. 2 is a schematic diagram illustrating cross-sectional view of a circuit connecting structure according to an embodiment of the present invention.

FIG. 3A is a schematic cross-sectional view of a circuit connecting structure including an insulating layer, a conductive layer, and a conductive pad according to an embodiment of the present invention.

FIG. 3B is a schematic diagram illustrating cross-sectional view of a circuit connecting structure including an additional insulating layer and a conductive layer according to an embodiment of the present invention.

FIG. 3C is a schematic diagram illustrating cross-sectional view of a circuit connecting structure including two additional via holes according to an embodiment of the present invention.

FIG. 3D is a schematic diagram illustrating cross-sectional view of a circuit connecting structure including two additional conductive layers in the two via holes respectively according to an embodiment of the present invention.

FIG. 4 is a schematic flow chart diagram illustrating steps of fabrication method of a circuit connecting structure according to an embodiment of the present invention.

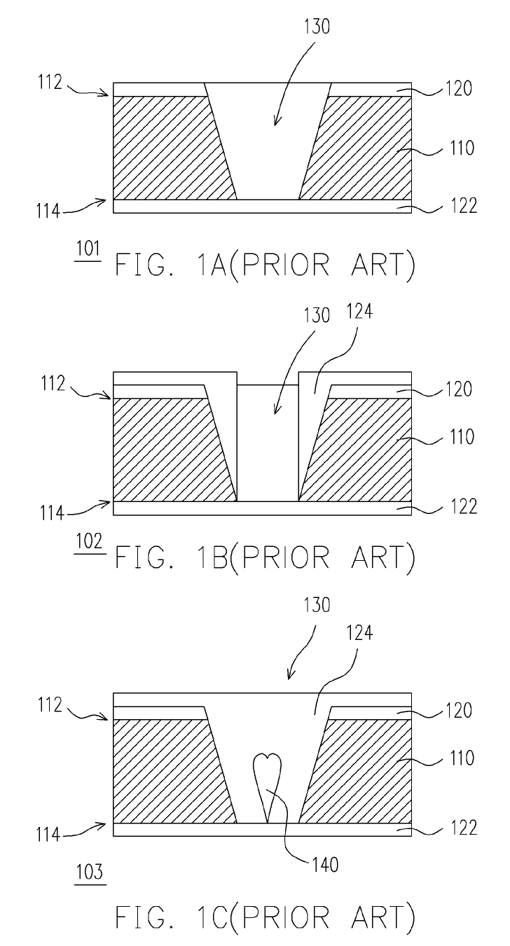

### DETAILED DESCRIPTION

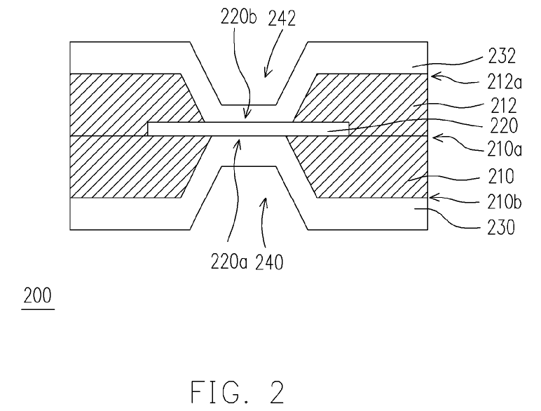

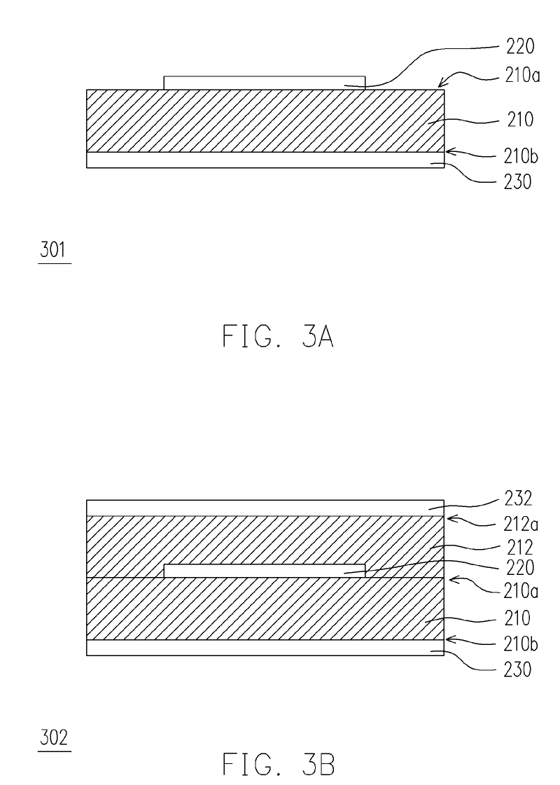

Referring to FIG. 2, it illustrates a schematic diagram of cross-sectional view of a circuit connecting structure according to an embodiment of the present invention. The circuit connecting structure 200 according to the present invention is embodied with a double-layered substrate, for example, and is applied to a circuit carrier (not illustrated), wherein the circuit carrier includes at least two patterned circuit layers (not illustrated). The circuit connecting structure 200 includes two insulating layers 210 and 212, a conductive pad 220, two conductive layers 230 and 232, wherein a via hole 240 is formed from the insulating layer 210 through the insulating layer 210, and a via hole 242 is formed from the insulating layer 212 through the insulating layer 212, where the insulating layer 212 is formed over the insulating layer 210. The conductive pad 220 is disposed between the two insulating layers 210 and 212, and the two surfaces 220a and 220b of the conductive pad 220 are connected to the via holes 240 and 242 respectively. The conductive layer 230 is disposed on the surface 210b of the insulating layer 210 and in the via hole 240 for connecting to the conductive pad 220. The conductive layer 232 is disposed on the surface 212a of the insulating layer 212 and in the via hole 242 for connecting to the conductive pad 220, and the conductive layer 230 and 232 serve to form a patterned circuit layer respectively. The material of the insulating layer 210 and 212 includes epoxy resin, and the material to the conductive pad 220 and conductive layers 230 and 232 includes copper, for example, such that the two conductive layers 230 and 232 are electrically connected to each other via the conductive pad 220.

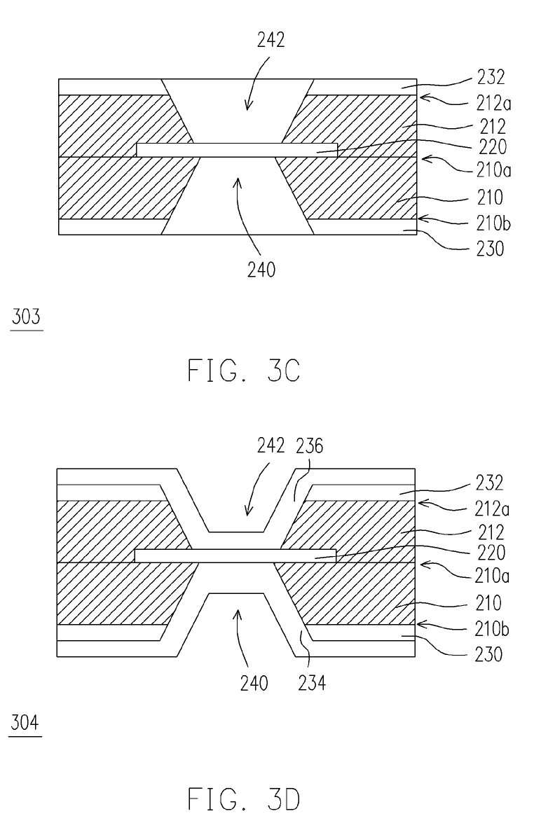

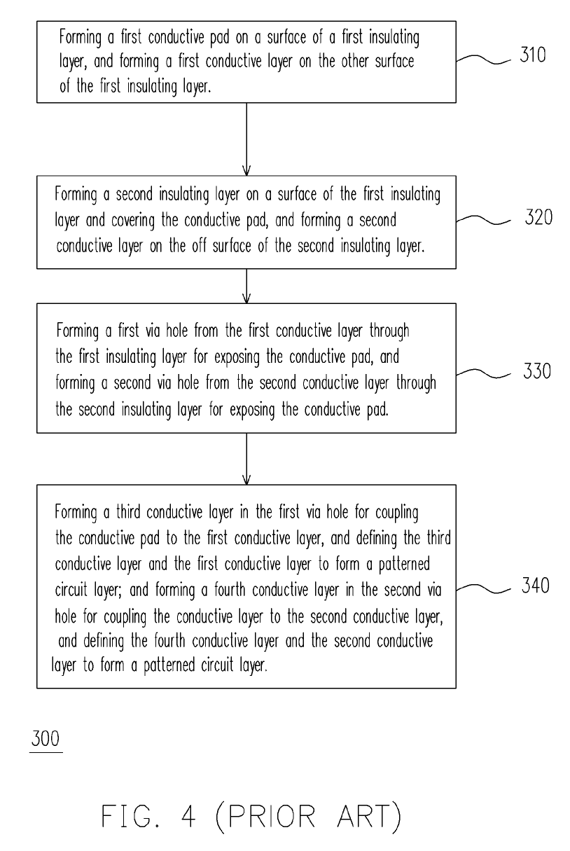

Referring to FIG. 4, it illustrates a schematic flow chart of a fabricating method of the circuit connecting structure according to one embodiment of the present invention. In FIG. 3A, a schematic diagram of cross-sectional view of a circuit connecting structure according to one embodiment of the present invention is depicted, including an insulating layer, a conductive layer, and a conductive pad. Referring to FIG. 4 and 3A together, a fabricating method of the circuit connecting structure includes the following steps. First, forming a conductive pad 220 over a surface 210a of an insulating layer 210, i.e. the first insulating layer cited in step 310. The defining method of the conductive pad 220 includes etching, for example, and forming a conductive layer 230, i.e. the first conductive layer cited in step 310, over a surface 210b of the insulating layer 210.

In FIG. 3B, it illustrates a circuit connecting structure depicted in FIG. 3A with additional one insulating layer and a conductive layer. Referring to FIG. 4 and 3B together, forming an insulating layer 212, i.e. the second insulating layer in step 320, over a surface 210a of the insulating layer 210 covering the conductive pad 220, and forming a conductive layer 232, i.e. the second conductive layer cited in step 320, over a surface 212a of the insulating layer 212. The fabricating procedure of the additional insulating layer 212 and conductive layer 232 includes compressing a resin coated copper or compressing a resin then plating a copper film, for example.

Referring to FIG. 3C, it is a schematic diagram illustrating cross-sectional view of a circuit connecting structure depicted in FIG. 3B, where two via holes are further formed. Referring to FIG. 4 and 3C together, forming a via hole 240, i.e. the first via hole cited in step 330, from the conductive layer 230 through the insulating layer 210 for exposing the conductive pad 220, and forming a via hole 242, i.e. the second via hole cited in step 330, from the conductive layer 232 through the insulating layer 212 for exposing the conductive pad 220. The via holes 240 and 242 are formed with procedures such as laser drilling, mechanics drilling, plasma etching, or photolithography method.

Referring to FIG. 3D, it is a schematic diagram illustrating cross-sectional view of a circuit connecting structure depicted in FIG. 3C, where two conductive layers are added in the two via holes. Referring to FIG. 4 and 3D together, forming a conductive layer 234, i.e. the third conductive layer cited in step 340, in the via hole 240 for connecting the conducting pad 22 with the conductive layer 230, and defining the conductive layer 234 and 230 for forming a patterned circuit layer. Moreover, forming a conductive layer 236, i.e. the fourth conductive layer cited in step 340, in the via hole 242 for connecting the conductive pad 220 and the conductive layer 232, and defining the two conductive layers 230 and 232 to form a patterned circuit layer, such that the two conductive layers 230 and 232 are electrically coupled to each other via the conductive pad 220. The additional conductive layers 234 and 236 in the via holes 240 and 242 are fabricated with electrical electroplating or plug electroplating method, or with a filling method with metal paste, a conductive polymer, etc., whereas the defining method includes photolithography method, for example.

According to the circuit connecting structure and fabricating method in the above descriptions, since a conductive pad is disposed between two insulating layers, the two conductive layers are electrically coupled to each other via the conductive pad. Therefore, a depth of the via hole according to an embodiment of the present invention is reduced to about temp60tempμm, for example, such that a depth/width ratio of via hole is substantially reduced with the width remains about the same. Furthermore, the conductive layer formed in the via hole is distributed more uniformly for avoiding voids or bubbles that may occur in the conductive layer in the via hole. Higher reliability for forming additional layers in the via holes is provided according to the circuit connecting structure in the present invention.

Although the invention has been described with reference to a particular embodiment thereof, it will be apparent to those skilled in the art that modifications to the described embodiment may be made without departing from the spirit of the invention. Accordingly, the scope of the invention will be defined by the attached claims and not by the above detailed description.

1. A circuit connecting structure, for a circuit carrier, wherein the circuit carrier comprises a first patterned circuit layer and a second patterned circuit layer, the circuit connecting structure comprising:
a first insulating layer, wherein a first via hole is formed therefrom;
a second insulating layer, wherein a second via hole is formed therefrom, and the second insulating layer is formed over the first insulating layer;
a conductive pad, disposed between the first insulating layer and the second insulating layer, wherein two surfaces of the conductive pad are respectively connected to the first via hole and the second via hole;
a first conductive layer, disposed over the first insulating layer away from a surface of the second insulating layer and in the first via hole for coupling to the conductive pad, and the first conductive layer serving to form the first patterned circuit layer; and
a second conductive layer, disposed over the second insulating layer away from a surface of the first insulating layer and in the second via hole for coupling to the conductive pad, and the second conductive layer serving to form the second patterned circuit layer.

2. The structure as recited in claim 1, wherein the conductive pad comprises copper.

3. The structure as recited in claim 1, wherein the first conductive layer comprises copper.

4. The structure as recited in claim 1, wherein the second conductive layer comprises copper.

5. The structure as recited in claim 1, wherein the first insulating layer comprises epoxy resin.

6. The structure as recited in claim 1, wherein the second insulating layer comprises epoxy resin.

7. A fabricating method of a circuit connecting structure, for a circuit carrier, wherein the circuit carrier comprises a first patterned circuit layer and a second patterned circuit layer, the fabricating method comprising:
providing a conductive pad, formed over a surface of a first insulating, and forming a first conductive layer over the other surface of the first insulating layer;
forming a second insulating layer over the surface of the first insulating layer and covering the conductive pad, and forming a second conductive layer over a surface of the second insulating layer that is away from the first insulating layer;
forming a first via hole from the first conductive layer through the first insulating layer for exposing the conductive pad, and forming a second via hole from the second conductive layer through the second insulating layer for exposing the conductive pad;
forming a third conductive layer in the first via hole for connecting the conductive pad with the first conductive layer, and defining the third conductive layer and the first conductive layer into the first patterned circuit layer; and
forming a fourth conductive layer in the second via hole for connecting the conductive pad with the second conductive layer, and defining the fourth conductive layer and the second conductive layer into the second patterned circuit layer.
